(19) United States
(12) Patent Application Publication
(10) Pub. No.: US 2005/0073323 A1
(43) Pub. Date: Apr. 7, 2005

(54) Measuring method and apparatus of thin film thickness

(76) Inventors: Ryuji Kohno, Chiyoda (JP); Tatsuya Nagata, Ishioka (JP); Naoki Watase, Kashiwa (JP); Michihiro Watanabe, Tsuchiura (JP)

Correspondence Address: ANTONELLI, TERRY, STOUT & KRAUS, LLP, 1300 NORTH SEVENTEENTH STREET, SUITE 1800, ARLINGTON, VA, 22209-9889, US

(21) Appl. No.: 10/902,132

(22) Filed: Jul. 30, 2004

(30) Foreign Application Priority Data
Oct. 6, 2003 (JP) 2003-346805

(51) Int. Cl. G01R 27/26

(52) U.S. Cl. 324/662

(57) ABSTRACT

In an apparatus for measuring thickness of a thin film, which is formed through a conductor, preventing the measurement from an error due to the curve or bend on a substrate surface or a moving surface of a stage, but without necessity of a large-scaled facility, an electric filed is applied between a probe 10 and a stage 8, so as to obtain an electrostatic capacitance of the substrate 3, an electrostatic capacitance of an insulating film, which is formed between the substrate 3, and an electrostatic capacitance defined starting from the substrate 3 to the thin film 4. The electrostatic capacitance between the substrate 3 and the thin film 4 is measured at plural numbers of places covering over the entire surface of the thin film 4. The probe 10 is so supported that the contact load “P” comes to be constant, by the probe 10 onto the thin film 4. A contact area of the probe 10 between the thin film 4 is calculated out through a predetermined equation, assuming the load “P” is constant. From respective electrostatic capacitances and the contact area measured, a distribution of thickness of the thin film 4 over the entire area thereof.

### BACKGROUND OF THE INVENTION

The present invention relates to a method and an apparatus for measuring thickness of a thin film, and it relates, in particular, to a measuring method and an apparatus thereof, for making a measurement on a thin film formed upon a semiconductor substrate and/or a glass substrate for use of a flat display panel, etc., through or putting a conductive layer of a transparent electrode therebetween, about the thickness and a distribution thereof.

In the field of semiconductors or flat display panels, such as thin-film structures made of a dielectric substance are applied many, into the structures and the manufacturing processes thereof; for example, a photo resist, an orientation film for controlling an orientation of a liquid crystal, a color filter, a transportation layer of electrons or holes, a light emission layer, etc.

Conventionally, those thin-film structures are manufactured by forming a film through a vacuum process and/or a spin coating process, etc.; however, in recent years, a challenge is started for making up them through a process of ink-jet with applying a micro-nozzle therein.

FIG. 23 attached herewith is a view for explaining the process for forming a film by means of the ink-jet (through an ink-jet film forming process). In this FIG. 23, with the ink-jet film forming process, a film is formed upon the surface of a substrate 3, through making scan on the substrate 3 by means of a head 2, which emits or injects a very small liquid drop of film material, continuously, while controlling the liquid drop.

With such the film-forming process of using the ink-jet technology therein, as was mentioned above, it can be expected that no large-scaled vacuum processing apparatus is needed, as well as, obtaining an improvement on the throughput, and an increase of an efficiency of using the film material, etc.

Among those thin-film structures mentioned above, in particular, an orientation film must be formed to be as thin as possible, for rising up or enhancing the characteristics or performances of a device produced, such as, at present, it is formed to be about several nm in thickness thereof, for example. Also, since the orientation film is small in the absolute value of the thickness, unevenness of the thickness thereof directly gives an ill influence upon the distribution of brightness on a display screen; therefore, being strongly requested to be formed, uniformly, in particular, in the thickness all over the entire film surface thereof.

Explanation will be made about the uniformity in the thickness in more details thereof, while picking up the orientation film as an example, by referring to FIG. 24 attached herewith. This FIG. 24 is a partial cross-section perspective view for illustrating the substrate 3 and a part of the thin film 4, which is formed on the substrate through a transparent electrode 6.

In this FIG. 24, in accordance with this ink-jet process, the film is formed through scanning of the ink-jet head onto the substrate 3, which emits or injects the liquid drop in a line-like shape. Because the liquid drops begin drying thereon when hitting upon the surface of the substrate 3; therefore, it is difficult to obtain a standardization, completely, in particular, between the liquid drops along the scanning lines being adjacent to each other, where a time difference is caused between them on the timing of hitting; i.e., for this reason, resulting into the so-called scanning stripes (i.e., unevenness in the thickness thereof) 5, as shown in the figure.

Those scanning stripes 5 produce a stripe-like pattern (i.e., unevenness of brightness), after the being applied into the display device, in particular, under the condition that the display screen is lighted up; therefore, it is impossible to obtain a picture of high quality, thereby bringing about a problem on the performances thereof.

As a problem other than that mentioned above, there can be also listed up a phenomenon, that a rising or projection 7 is made up around an outer periphery of the thin film. This is because the outer periphery portion of the thin film 4 is large in a drying is area; i.e., the contact area with an outside air, comparing to that of a central portion thereof, in particular, for a portion of the side surface thereof, and therefore, it is said that it is causes by a phenomenon (so-called the coffee stain), where a solute of the film material is attracted to the outer periphery portion.

Thus, due to such the mechanisms where the solute of the film material is attracted up to the outer periphery portion, there can be caused that phenomenon, if a gap is caused between the liquid drops between the scanning lines, even only a little bit; for example, when a specific nozzle among the ink-jet head causes blocking or plugging therein, since there is defined an outer periphery of the liquid drop, and therefore, the drying area comes to be large in the area, thereby producing the rising or projection 7 even at the central portion of the display panel. This phenomenon also gives the ill influence upon the performances of the display, as a result thereof.

In the above, though the description was made about the surface conditions and the problems, especially, in the ink-jet film forming process for forming the orientation film to be used in the display, as an example thereof; however, also in the field of electronics, such as, the semiconductor devices and the display devices, for example, for any one among almost of the various kinds of such the thin-film structures as was listed above, it is also requested that the film is thin and uniform in the thickness thereof, in the similar manner as was mentioned above.

Also, not only limiting in the ink-jet film forming process, but also in the film forming method, such as, through the spin coating and a screen printing, for example, it is considered important to obtain the thickness and the distribution thereof, in particular, on the formed thin film, from a view point of achieving a process development or management upon manufacturing process thereof.

However, the absolute value and the unevenness of the thickness on the thin film is an order of “nm”, being very small; therefore, it is not easy to make a measurement thereof.

In the conventional arts, an estimation on the thickness of a function film, which is formed on a glass substrate of the flat panel display, for example, it is carried out with using a contact-type step meter, a scanning-type probe microscope, such as, an atomic force microscope (hereinafter, be described by “AFM”), for example, and an optical film thickness measuring apparatus; thus, upon basis of those principles, various kinds of measuring apparatuses or devices are already known.

Also, as other measuring method for the film thickness, there is described a method, in which measurement is made on the statistic capacitance aiming the dielectric substance as a target, so as to identify the thickness thereof, such as, in the following Patent Document 1, for example.

The technology described in the Patent Document 1 relates to an accumulated layer method for enabling the measurement of the thickness of an accumulated film accumulating on a chamber interior wall, at any time, and there is described a film forming apparatus having a reproducible measuring monitor for an accumulated film, in which measurement is made on the statistic capacitance or the resistance value of the accumulated film, thereby obtaining the thickness thereof.

On the other hand, the technology described in Patent Document 2 relates to a film thickness measuring method for measuring the thickness of a dielectric substance having a curved surface, in a non-destructive manner and a short time-period, but at high accuracy. And, the technology described in this Patent Document 2 is a method for measuring the thickness of the dielectric substance, through measurement of the statistic capacitance and the dielectric constant of the dielectric substance, and it comprises a step for applying an electric field on the dielectric substance in a direction of thickness thereof with an aid of a measuring terminal or a probe and an electrode, a step for measuring a contact area between the measuring terminal and the dielectric substance, and a step for obtaining the thickness of the dielectric substance from the values of the electric field and the contact area.

Patent Document 1: Japanese Patent Laying-Open No. Hei 10-189560 (1998); and

Patent Document 2: Japanese Patent Laying-Open No. Hei 11-108608 (1998).

### BRIEF SUMMARY OF THE INVENTION

As was mentioned above, for the function thin films to be applied in the field of the electronics of, such as, the semiconductor devices and the flat display devices, it is required to be small in the absolute value of the thickness and also the unevenness or fluctuation thereof, all over the entire surface of the thin film formed, in many cases.

In particular, in the field of the flat panel display, corresponding to the trend or tendency of enlarging the panel sizes thereof in recent years, such as, 1 m square, etc., for example, it is useful to make measurement upon the film thickness over a wide region thereof, covering the entire surface of the panel thereof, for example, in the manufacture process of the display device or in the management on the manufacturing process thereof.

With such the contact-type step meter relating to the conventional art mentioned above, however, there is a problem; i.e., principally, it is difficult to make the measurement on the film thickness over the wide range thereof. This will be explained below, by referring to FIGS. 25 and 26 attached.

FIG. 25 is a typical view for showing a measurement result on height of the thin film surface in relation to the scanning position, when measuring through the contact-type step meter of the conventional art. Also, FIG. 26 is a typical view for showing an actual distribution of the film thickness.

With such the contact-type step meter, however, since it is necessary to control the height of a contactor, finely or minutely, at each point of measurements, so that the contact load comes to be constant between the surface to be measured and the contactor, thereby outputting a control signal of an amount thereof as to be the height of the surface; therefore, it sometimes outputs a value including therein a component of an unknown curve or bend and/or winding, etc., if such lies upon a stage for mounting a substrate thereon, on which is formed the thin film to be measured.

For this reason, upon the measurement of the thin film covering over a whole area of a large substrate, in particular, as shown in FIG. 26 mentioned above, there is a problem that a desired output cannot be obtained, i.e., corresponding to the actual distribution of the film thickness, and also that the film thickness is ambiguous at an arbitrary position.

Next, with the SPM of the conventional art, such as the AFM, for example, generally, it is known that it can detects the condition upon the surface, very accurately. However, it is absolutely impossible to make the measurement, covering over the range, widely, such as, 1 m square, for example.

Further, with the conventional optical-type film thickness measurement apparatus, it is not easy to obtain and set up the optical values of physical property of the thin film to be measured; therefore, there is a problem of taking labor to make the measurement thereupon.

Moreover, with such the conventional optical-type film thickness measurement apparatus, the apparatus itself is large in the sizes thereof, such as, from a viewpoint of the principle thereof, and the circumferential environment thereof gives ill influences upon the result of measurement; therefore, there is a problem that a lot of cost is necessary to keep a suitable place for installation thereof.

Further, with such the conventional optical-type film thickness measurement apparatus, an area for measurement, i.e., a spot of a light, at a certain place of measurement, is large in the diameter thereof, such as, from several hundreds μm up to several mm, therefore it is impossible to make a detection upon the surface condition of a very small or minute area smaller than that. For this reason, there is a problem, for example, that it is impossible to grasp the shape, such as, the configuration of an edge portion on an outer periphery of the thin film, a sudden or unexpected recess or projection, etc., upon the surface of the thin film surface.

Also, with such the measuring method of a film thickness described in the Patent Document 1 mentioned above, a pair of contactors are fixed, each then scanning cannot be made on a large area or region on the surface of the thin film formed; therefore, it is difficult to gasp the distribution of the film thickness on the surface of the formed thin film.

Further, with such the measuring method of the film thickness of the Patent Document 1, since both the pair of the contactors are flat at the tip thereof; therefore, a measurement area is large, so that it is difficult to detect the surface condition thereof within a minute area or region.

Moreover, with such the measuring method of the film thickness of the Patent Document 1, since the film is directly accumulated upon the contactor, so as to obtain the same condition to the accumulated layer, which is formed on an interior wall of the chamber, therefore, it has a drawback that the contactor cannot be used repetitively.

Also, with such the measuring method for the film thickness shown in the Patent Document 2, it may be considered to be an effective way when the target to be measured is a single body of the thin film, for example; however, in the case when the target to be measured is the thin film, under the condition where it was already formed on the substrate made from a dielectric substance, such as, a glass plate or the like, it is difficult to measure the film thickness thereof, since the measured value includes an electrostatic capacitance of the substrate therein.

An object according to the present invention is to provide a method for measuring the thickness of such the thin film formed through or putting the conductive layer therebetween, enabling the measurement protecting from an error thereof due to the curve and/or the winding on the surface of a substrate and/or a stage, but without necessitating a large-scaled facility, and also enabling to grasp the minute surface configurations covering over a wide range.

For accomplishing the object mentioned above, according to the present invention, there are provided the followings:

(1) A thin-film thickness measuring method, for measuring thin-film thickness of an insulating thin-film, which is formed on a substrate through at least a conductor layer, comprising the following steps of: a step for directing said substrate to be in contact with a stage, which is made of a conductor, facing a reverse surface thereof, on a front surface thereof being formed a thin film; a step for brining a coaxial probe to be in contact with said substrate on a surface thereof, thereby measuring an electrostatic capacitance of said substrate; a step for brining the coaxial probe to be in contact with said thin film on a surface is thereof, so as to make said coaxial probe scanning in a surface direction of the thin film, thereby measuring electrostatic capacitances, each being composed of said substrate and said thin film, at plural numbers of positions; and a step for calculating and extracting plural numbers of electrostatic capacitive components of said thin film from said electrostatic capacitances measured, thereby converting into thickness of said thin film.

(2) A thin-film thickness measuring apparatus for measuring thin-film thickness of an insulating thin-film, which is formed on a substrate through at least a conductor layer, comprising: a stage having a conductor surface for mounting said substrate thereon; a coaxial probe; a means for measuring an electrostatic capacitance of said substrate between said coaxial probe and said stage, and also electrostatic capacitances composed of those of said substrate and said thin film; a means for moving said coaxial probe and said stage, relatively; a means for calculating and extracting electrostatic capacitive component of said thin film from said electrostatic capacitance measured, thereby converting it into thickness thereof; and a means for recording therein the thickness converted.

(3), (4) Preferably, in the thin-film thickness measuring method or an apparatus thereof described in the above (1) or (2), a tip of said coaxial probe is substantially spherical on a surface thereof.

(5), (6) Or,preferably, in the thin-film thickness measuring method or an apparatus thereof described in the above (1) or (2), or (3) or (4), said coaxial probe are provided in plural numbers thereof, and the electrostatic capacitance of said substrate and the composed electrostatic capacitance of said substrate and said thin film are measured, separately, by means of different coaxial probes.

(7) Or, preferably, in the thin-film thickness measuring method described in the above (1), contact pressure between said is coaxial probe and said thin film is made nearly equal during a time-period when said coaxial probe scans in the direction of surface direction of the thin film, by means of a probe supporting means, and the thickness of the thin film is converted, by using a contact area between said probe and the thin film, which is calculated out from this contact pressure, a dip radius of said coaxial probe, material property of the probe, and material property of the thin film.

(8) Or, preferably, in the thin-film thickness measuring apparatus described in the above (1), it further comprises a probe supporting means for keeping contact pressure between said coaxial probe and said thin film to be nearly equal, during a time-period when said coaxial probe scans in the direction of surface direction of the thin film, wherein the thickness of the thin film is converted, by using a contact area between said probe and the thin film, which is calculated out from this contact pressure, a dip radius of said coaxial probe, material property of the probe, and material property of the thin film.

(9) Or, preferably, in the thin-film thickness measuring apparatus described in the above (1), contact pressure between said coaxial probe and said thin film is detected, and the thickness of the thin film is converted, by using a contact area between said probe and the thin film, which is calculated out from this contact pressure, a dip radius of said coaxial probe, material property of the probe, and material property of the thin film.

(10) Or, preferably, in the thin-film thickness measuring apparatus described in the above (2), further comprises a contact pressure detecting means for detecting contact pressure between said coaxial probe and said thin film, wherein the thickness of the thin film is converted, by using a contact area between said probe and the thin film, which is calculated out from this contact pressure, a dip radius of said coaxial probe, material property of the probe, and material property of the thin film.

### BRIEF DESCRIPTION OF THE SEVERAL VIEWS OF THE DRAWING

Those and other objects, features and advantages of the present invention will become more readily apparent from the following detailed description when taken in conjunction with the accompanying drawings wherein:

FIG. 1 is a schematic structural view for showing an entire of an apparatus for measuring thickness of a thin film, according to an embodiment of the present invention;

FIG. 2 is an upper view for showing an example of a target to be measured therewith;

FIG. 3 is a cross-section view along with the line A-A in FIG. 2 mentioned above;

FIG. 4 is a cross-section view for showing other example of the target to be measured therewith;

FIG. 5 is a cross-section view for briefly showing the principle portions of a probe and the target to be measured;

FIG. 6 is a cross-section view for showing an example of a tip portion of the probe;

FIG. 7 is a cross-section view for showing other example of the tip portion of the probe;

FIG. 8 is a view for explaining a component of the electrostatic capacitance, in one example of the targets to be measured;

FIG. 9 is a view for explaining a component of the electrostatic capacitance, in other example of the targets to be measured;

FIG. 10 is a brief cross-section view for showing a means of obtaining the electrostatic capacitance of a substrate or an insulation film;

FIG. 11 is a brief cross-section view for showing an outlook of the probe in condition of contacting on a thin film, as the target to be measured;

FIG. 12 is also a brief cross-section view for showing an outlook of the probe in condition of contacting on the thin film, as the target to be measured, but inclining in the condition thereof;

FIG. 13 is a view for showing a cantilever for mounting the probe on a probe supporting mechanism having a fulcrum;

FIG. 14 is a view for showing several examples of the conditions where the probe contacts on the surface of an arbitrary thin film;

FIG. 15 is a perspective view for showing the probe supporting mechanism provided for always keeping a contacting load of the probe upon the thin film to be constant;

FIG. 16 is a partial cross-section view of the probe and the target to be measured shown in FIG. 15 mentioned above;

FIG. 17 is a cross-section view for showing a probe supporting structure, being provided for keeping the contacting load to be constant;

FIG. 18 is a view for showing a relationship between a film thickness (m) and a resolution of thickness (m), upon measurement of the thickness with using the measuring apparatus of the thin film according to the present invention;

FIG. 19 is an upper view of a thin film portion, which is formed through an ink-jet process, for showing an example of a is scanning direction of the probe;

FIG. 20 is an upper view of a thin film portion, which is formed through an ink-jet process, for showing other example of a scanning direction of the probe;

FIG. 21 is a perspective view of a measuring apparatus, for showing other embodiment according to the present invention;

FIG. 22 is a flowchart of a manufacturing process of a flat display panel, into which the measuring method of the thin film thickness according to the present invention;

FIG. 23 is a view for explaining an ink-jet film forming process;

FIG. 24 is a partial perspective view including a cross-section thereof, for showing a part cut out from the thin film, which is formed on a substrate through a transparent electrode thereon;

FIG. 25 is a typical view for showing a result of measurement on height of the thin film surface, when measuring it with using the contact-type step meter of the conventional art; and

FIG. 26 is a typical view for showing an actual distribution of the film thickness.

### DETAILED DESCRIPTION OF THE INVENTION

Hereinafter, embodiments according to the present invention will be fully explained by referring to the drawings attached herewith.

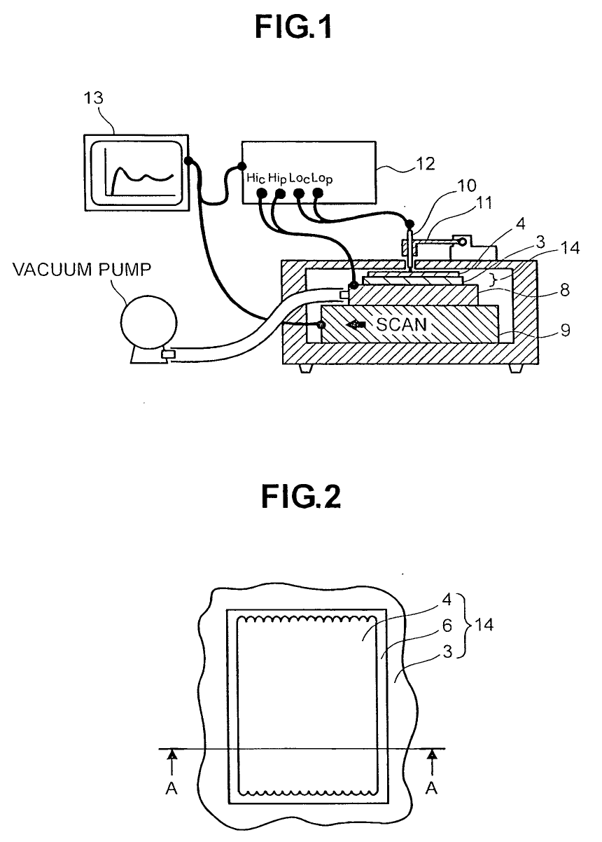

FIG. 1 is a schematic structural view for showing an entire of an apparatus for measuring thickness of a thin film, according to an embodiment of the present invention. In this FIG. 1, a substrate 3 and a thin film 4 formed thereon through or putting a transparent film therebetween (not shown in the figure), forming a target 14 to be measured (hereinafter, “measuring target”), they are mounted on a wafer stage made of a conductor, while being absorbed through vacuum.

Those of the substrate 3, the measuring target 14 and the wafer stage 8 are provided on an x-y stage 9. On the other hand, a probe 10 is attached at a tip portion of a cantilever 11, and it is in contact with the thin film 4 upon the surface thereof, due to the gravity acting thereon. The probe 10 and the wafer stage 8 are connected to LCR meter 12, respectively. Applying an electric field between the probe 10 and the wafer stage 8 under this condition, it is possible to measure the electrostatic capacitance “C” in the direction of thickness on the measuring target 14.

Further, bringing an electric potential on a side of the probe 10 to be “Lo” while that on a side of the wafer stage 8 to be “Hi”, when measuring the electrostatic capacitance, it is possible to keep noises mixing or introduced into the measured value to be small.

Among those electrostatic capacitances, if it is assumed that the electrostatic capacitance of the thin film 4 is “Cp”, then a relationship is established between the film thickness “d” and the “Cp”, in relation to the capacitance produced between parallel flat plates, which can be expressed by the following equation (1):
Cp=εo×εr×S/d (1)
Where, “εo” is a dielectric constant of vacuum, “εr” a dielectric constant of the thin film 4, and “S” an area between the parallel flat plates.

Accordingly, if determining the area “S”, as well as, extracting the component of the electrostatic capacitance “Cp” of the thin film 4 from the electrostatic capacitance “C”, it is possible to obtain the film thickness “d” of a portion of the thin film 4, on which the probe 10 is in contact with.

Also, if moving the probe 10 within the surface of the thin film 4 by means of the xy stage 9, in relative to the thin film 4, it is possible to obtain a distribution of the film thickness “d” over the entire surface of the thin film 4. Further, a processing device (or processor) 13 carries out the driving on the xy stage 9, calculation of the film thickness “d” at each point, and recording of the calculated value thereof, etc.

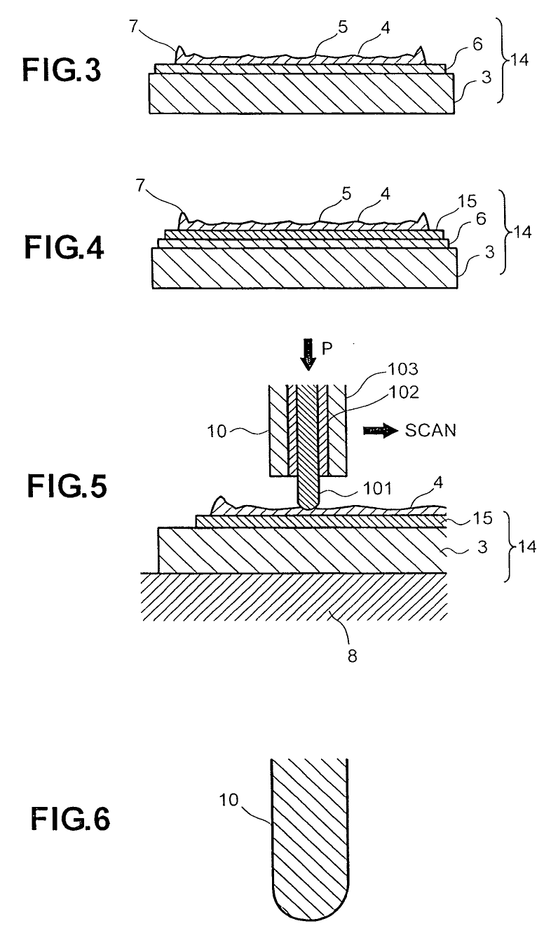

Next, explanation will be made on the measuring target 14, by referring to FIGS. 2 and 3 attached. This FIG. 2 is an upper view of the measuring target 14, and FIG. 3 is the cross-section view along the line A-A shown in FIG. 2 mentioned above.

In FIG. 2, upon the measuring target 14 is formed the thin film 4 through or putting a layer made of a transparent electrode 6 therebetween, on the upper surface of the substrate 3 made of glass plate. As is shown in FIG. 3, on the thin film 4 of an insulator, there is caused the phenomenon producing the scan stripes 5 and/or the projection or rising at an outer periphery portion thereof, accompanying with the scanning by means of the ink-jet header mentioned above, for example.

Next, FIG. 4 is the cross-section view in the similar manner to that shown in FIG. 3, however in a case where the measuring target is different from that shown in FIGS. 2 and 3 mentioned above. Upon the measuring target 14 shown in this FIG. 4, there is further formed a new insulator film 15 on the substrate 3, in particular, between the layer of the transparent electrode 6 and the thin film 4.

Next, explanation will be made about the vicinity of measuring portion of the electrostatic capacitance, according to the embodiment of the present invention shown in FIG. 1 mentioned above; i.e., the principle portions of the probe 10 and the measuring target 14, by referring to FIG. 5.

FIG. 5 is the cross-section view for showing the principle portions of the probe 10 and the measuring target 14, briefly. In this FIG. 5, the measuring target is mounted on the stage 8, and the probe 10 is in contact with the thin film 4 upon the upper surface thereof, as a part of the measuring target 14, with a load “P”. The probe 10 has a conductor 101 in contact with the thin film 4 of the measuring target 14, a conductor 103 being formed surrounding that conductor 101, and an insulator 102 being put between those conductors 101 and 103, i.e., having the so-called coaxial structure.

Explanation will be made about the tip configuration of the probe 10, by referring to FIGS. 6 and 7 attached.

FIGS. 6 and 7 show the cross-sections of the tip portion of the probe 10. The probe 10 shown in FIG. 6 is column-like, and the tip thereof is finished to be spherical surface-like, in the outer shapes thereof. With this, it is possible to obtain a preferable or superior contact, always, even if there is unevenness in a little bit upon the surface of the thin film on the measuring target 14.

And, the probe 10 shown in FIG. 7 is also column-like, but it is tapered-like from the vicinity of the tip portion thereof, and further it is finished to be spherical surface-like at the tip portion, in the shapes thereof. With doing so, it is possible to bring the contact area with the thin film 4 to be small, while maintaining the mechanical strength of the probe 10 (i.e., by letting a diameter of the probe 10 to be equal or greater than a predetermined value), thereby obtaining an improvement on the resolution of measurement upon the thin film.

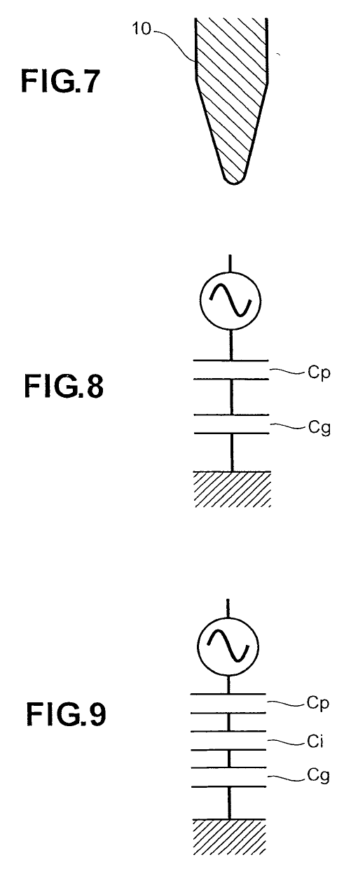

The electrostatic capacitive components of the composed electrostatic capacitance “C”, which can be obtained through the measurement of thin film thickness according to the embodiment of the present invention, will be shown in FIGS. 8 and 9 attached herewith, while explaining a method for extracting the electrostatic capacitive components of the thin film therefrom, which is necessary for calculating out the film thickness of the thin film 4.

FIG. 8 is a view for explaining the electrostatic capacitive components of the measuring target 14 shown in FIG. 5 mentioned above, wherein there are two (2) components; i.e., the electrostatic capacitance “Cp” of the thin film 4 and the electrostatic capacitance “Cg”, aligning to each other in series. In such the case, it is possible to extract or obtain the electrostatic capacitance “Cp” of the thin film 4, from the following equation (2):
1/C=(1/Cp)+(1/Cg) (2)

Also, FIG. 9 shows the electrostatic capacitive components of the measuring target shown in FIG. 4 mentioned above; i.e., there is further added the electrostatic capacitance “Ci” of the insulator film 15 in series, in addition to the electrostatic capacitive components shown in FIG. 8. In such the instance, the electrostatic capacitance “Cp” of the thin film 4 can be extracted or obtained, from the following equation (3):
1/C=(1/Cp)+(1/Cg)+(1/Ci) (3)

In this manner, it is possible to extract the electrostatic capacitive component, mathematically, if the layer structure of the measuring target is clear even when the layers are formed in plural number thereof.

For the purpose of calculating out the electrostatic capacitance “Cp” of the thin film 4, actually, with using those equations (2) and (3) in relation thereto, it is necessary that the electrostatic capacitance “Cg” or “Ci” is already known of the substrate 3 or the insulator film 15.

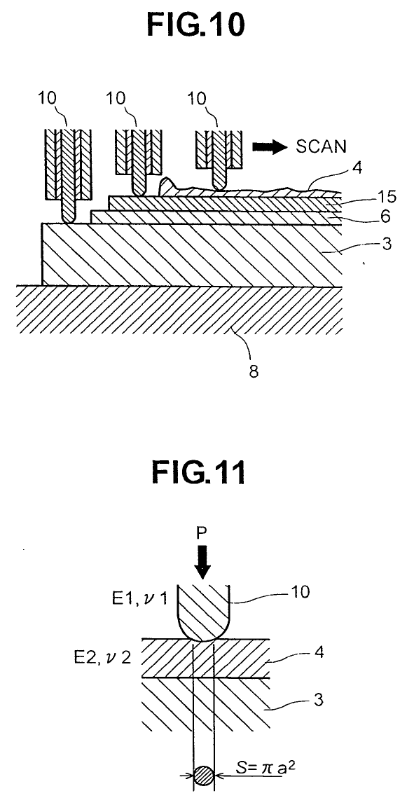

The method for calculating the above will be explained, by referring to FIG. 10 attached herewith. This FIG. 10 is a brief cross-section view for showing therein a means for obtaining the electrostatic capacitance “Cg” or “Ci” of the substrate 3 or the insulator film 15, upon measuring the target being similar to that shown in FIG. 4 mentioned above.

Three (3) pieces of probes 10-1, 10-2 and 10-3 are in contact with, from the left-hand side in FIG. 10, upon the surface of the substrate 3, the surface of the insulator film 15, and the surface of the thin film 4, respectively. The condition shown in this FIG. 10 is that in the vicinity of an edge portion of the measuring target 14; i.e., the substrate 3 or the transparent electrode 6 is exposing from the measuring target 14, while the thin film 4 exposing from the insulator film 15, in the vicinity of this edge potion.

Accordingly, in the vicinity of the edge portion of the measuring target 14, the probe 10-1 is in contact with 3 or the transparent electrode 6, upon the surface thereof, while the probe 10-2 being in contact with the insulator film 15 upon the surface thereof.

Applying an electric field between the stage 8, under the condition where the probes 10-1, 10-2 and 10-3 are as shown in FIG. 10, respectively, it is possible to obtain the electrostatic capacitances, i.e., the electrostatic capacitance of the substrate 3, the electrostatic capacitance of both the substrate 3 and the insulating film 15, and the electrostatic capacitance starting from the substrate 3 up to the thin film 4, respectively.

From a result of the measurement of those, it is possible to identify the electrostatic capacitances “Cg” and “Ci” of the substrate 3 and the insulator film 15, respectively. Though showing an example of using three (3) pieces of the probes 10-1, 10-2 and 10-3 herein, however it is also possible to make the measurement by means of one (1) probe 10 for measuring the film thickness, respectively, thereby to record the value obtained therefrom.

Also, among those three (3) pieces of the probes 10-1, 10-2 and 10-3, it is only the probe 10-3 for measuring the electrostatic capacitance from the substrate 3 up to the thin film 4 that is scanned in the direction shown by an arrow in FIG. 10.

Next, explanation will be given on a method for calculating out the area “S” of the parallel flat plates, i.e., the contact area between the probe 10 and the thin film 4. This FIG. 11 is a brief cross-section view for showing the condition where the probe 10 is in contact with the thin film 4 of the measuring target.

Assuming that a tip radius of the probe 10 is “R0”, the Young's module “E1”, the Poisson's ratio “ν1”, and then this probe 10 is in contact with the thin film 4 or the substrate 3, on which the thin film is formed, of the Young's module “E2”, and the Poisson's ratio “ν2”, at the load “P”, then the contact area comes to be circular in the shape thereof, wherein a radius “a” of this circle can be obtained from the following equation (4) of the Hertz's law in relation to the contact between a sphere and a flat surface, and the area calculated out to be the area “S” of the parallel flat plates:
A³=(¾)×R0×{(1−ν1²)/E1+(1−ν2²)/E2}×P (4)

FIG. 12 is a brief cross-section view for showing the condition where the probe 10 is contacted on the thin film 4 of the measuring target, under the inclining condition thereof. It is difficult to bring the probe 10 to be in contact with, strictly, while keeping the vertical axis thereof perpendicularly, therefore, in general, it is in contact with at a certain degree of an inclination, as shown in FIG. 12. Even in such the case, if the tip radius “R0” and the load “P” are constant, it can be considered that the contact area therebetween is constant.

As was mentioned above, the contact load of the probe 10 upon the measuring target gives an ill influence upon the contact area between the thin film 4, and further that the contact area also gives ill influence upon the result of calculation on the film thickness; therefore, it is desirable that the contact load of the probe 10 is always at the constant.

Also, if the contact load of the probe 10 is too much than that is necessary, since it pushes down the thin film 4, therefore the thin film is calculated out to be smaller than the inherent value of the film thickness thereof, and at the worst, it injures the surface of the thin film 4; therefore, it is desirable that the contact load is as small as possible.

Hereinafter, explanation will be made on a means for making the contact load of the probe 10 upon the thin film 4, being as small as possible.

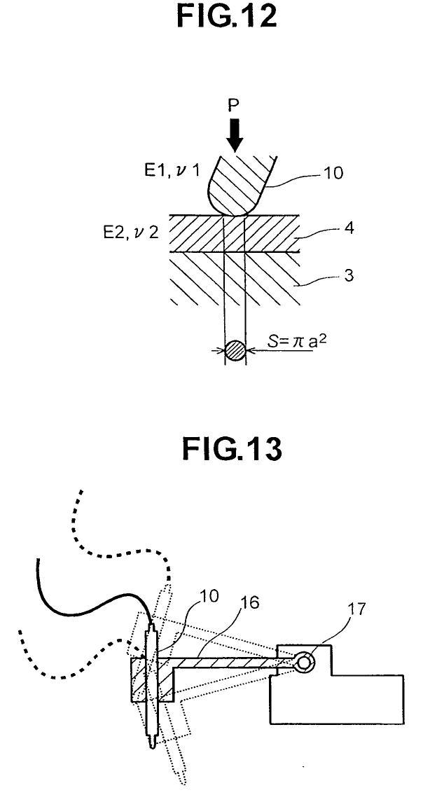

FIG. 13 is a view for showing a cantilever 16, which is mounted on a probe supporting mechanism, having the probe 10 and a fulcrum 17 therein. In this FIG. 13, the cantilever 16 is attached with the probe 10 at one end thereof, but the other end thereof is fixed onto the fulcrum 17, which is able to rotate freely.

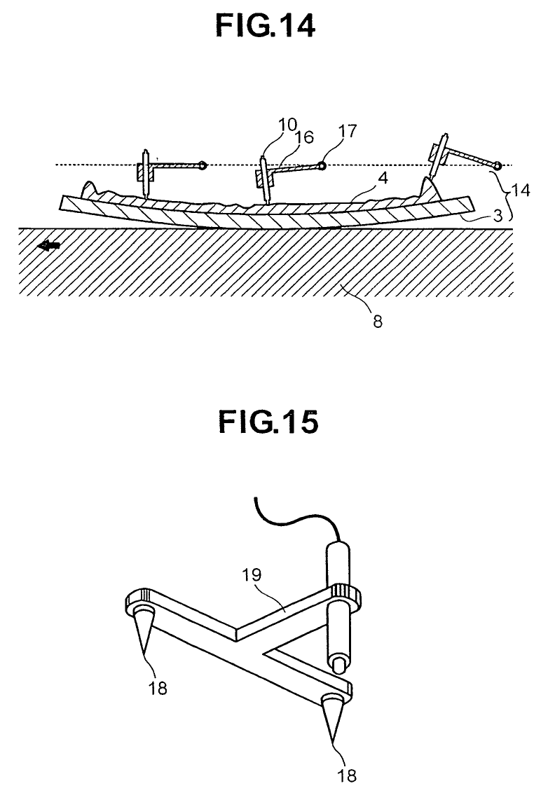

A several examples will be shown in FIG. 14; wherein the probe 10 is in contact with the thin film 4 on the surface thereof, arbitrarily, but with such the structure or mechanism as was mentioned above.

In this FIG. 14, the measuring target 14 has a curve or bend, which is caused unavoidably due to the manufacturing thereof, and it is mounted on the stage 8 under such the condition thereof. A broken line shown in FIG. 14 shows changes of the fulcrum 17 in the position thereof, in particular, when the probe 10 moves, in relative, upon the surface of the thin film 4.

As is shown in this FIG. 14, the cantilever 16 is scanned in the direction of the arrow, and it maintains the contact between the probe 10 and the thin film 4, while changing an inclination angle with respect to the broken line, freely, depending upon the height of the surface on the thin film 4. Further, in any condition thereof, it is possible to maintain the contact load of the probe 10 to be constant in the value thereof, which can be determined by the dead weights of the cantilever 16 and the probe 10.

FIG. 15 is a perspective view for showing the a supporting structure for always maintaining the contact load of the probe 10 upon the thin film 4 to be constant, in the similar manner to that of the example shown in FIG. 13 mentioned above.

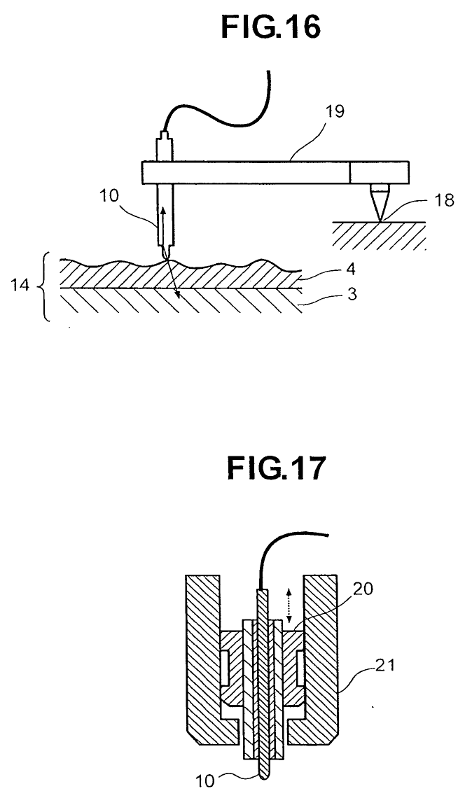

In this FIG. 15, the probe 10 is attached on a cantilever 19, which has two (2) fulcrums 18 therein. FIG. 16 shows the probe 10 under the condition of being in contact with the thin film on the surface thereof, with such the structure as was mentioned above. This FIG. 16 is a partial cross-sectional side view of the probe 10 and the measuring target, which are shown in FIG. 15 mentioned above.

In the example shown in FIG. 13 mentioned above, sliding resistance is generated at the fulcrum 17 when the cantilever 16 rotates. On the contrary to this, with the example shown in this FIG. 15, as is apparent from FIG. 16, since no such the sliding resistance is generated as is in the example shown in FIG. 13, then it is possible to bring the mechanical resistance to be almost zero (0) when the probe 10 follows the unevenness on the surface of the thin film 4; therefore, it is possible to obtain the contact being ideal much more.

FIG. 17 is a brief cross-section view for showing the probe supporting structure for always maintaining the contact load to be constant with respect to the thin film 4, in the similar manner to that of the example shown in FIG. 13 mentioned above.

In this FIG. 17, the probe 10 is attached on a housing 21 through a linear slider 20. The linear slider 20 moves within the housing 21 together with the probe 10, under the condition of maintaining the contact load of the probe 10 upon the thin film 4 to be nearly equal to and/or contestant.

With such the example shown in this FIG. 17, it is possible to keep the contact angle always to be constant, but without change in the contact angle of the probe 10 with respect to the thin film 4, depending upon the thickness of the thin film 4 at the contacting portion thereof.

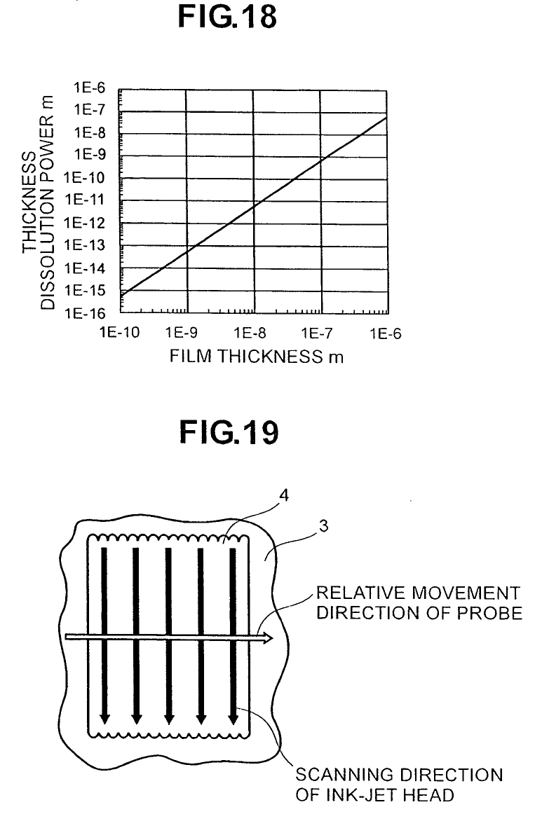

FIG. 18 is a view for showing a relationship between the film thickness (m) and the resolution power (m) of the thickness, upon measurement of the thickness, with using the thin film thickness measuring apparatus according to the present invention. As is shown in this FIG. 18, the smaller the film thickness, the higher the sensitivity on the measurement thereof.

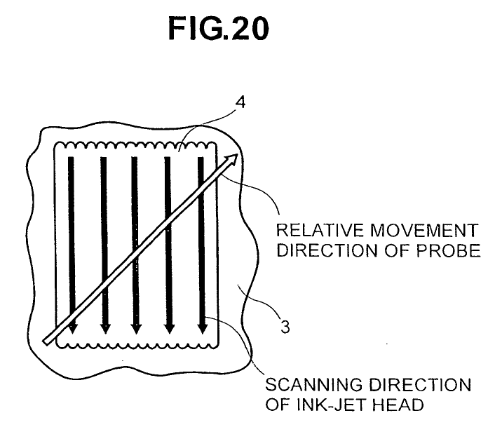

Following to the above, explanation will be given on the scanning direction of the probe 10 with respect to the measuring target by referring to FIGS. 19 and 20 attached herewith.

FIGS. 19 and 20 are upper views of the thin film portion, on which the thin film is formed through the ink-jet process. In this FIG. 19, it is indicated that the probe 10 relatively moves perpendicular to the scanning direction of the ink-jet head. With this operation, it is possible to evaluate the liquid injecting characteristic on each of nozzles, which are located in plural numbers thereof within the ink-jet head.

Also, in FIG. 20, it is indicated that the probe 10 is moved, relatively, inclining with respect to the scanning direction of the ink-jet head. With such the operation, it is possible to evaluate the time-change of the liquid injection characteristic for each of the nozzles.

In general, for the purpose of obtaining the detailed distribution of the film thickness, it is ideal to make the measurement in the two (2) dimensional manner (i.e., 2-D measurement), upon the entire area of the thin film surface; however, in a case when it is impermissible from a viewpoint of time or data processing, it is preferable to make an evaluation through one (1) dimensional scanning in the inclined direction, as is shown herein.

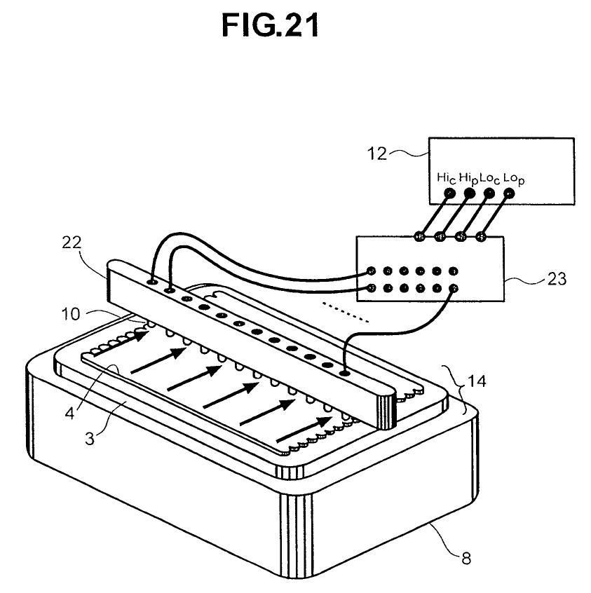

Next, FIG. 21 is a perspective view of the measuring apparatus, for showing other embodiment, according to the present invention. In this FIG. 21, it is so constructed that plural numbers of the probes 10 can contact onto the one (1) piece of the measuring target 14. Each of the probes is mounted on a probe head 22. And, the plural numbers of those probes 10 are connected to one (1) set of scanner 23, and the scanner 23 is connected to an LCR meter 12.

In this embodiment shown in FIG. 21, the probes 10 are scanned in the direction perpendicular to that of alignment of those plural numbers of probes 10, and outputs from the respective probes 10 are processed time-sequentially by a function of a scanner 23, thereby to be transmitted to the LCR meter 12.

With such the example as shown in FIG. 21 mentioned above, it is possible to obtain the three dimensional (3D) information about the distribution of the thin film thickness, but without bringing about a much increase of time.

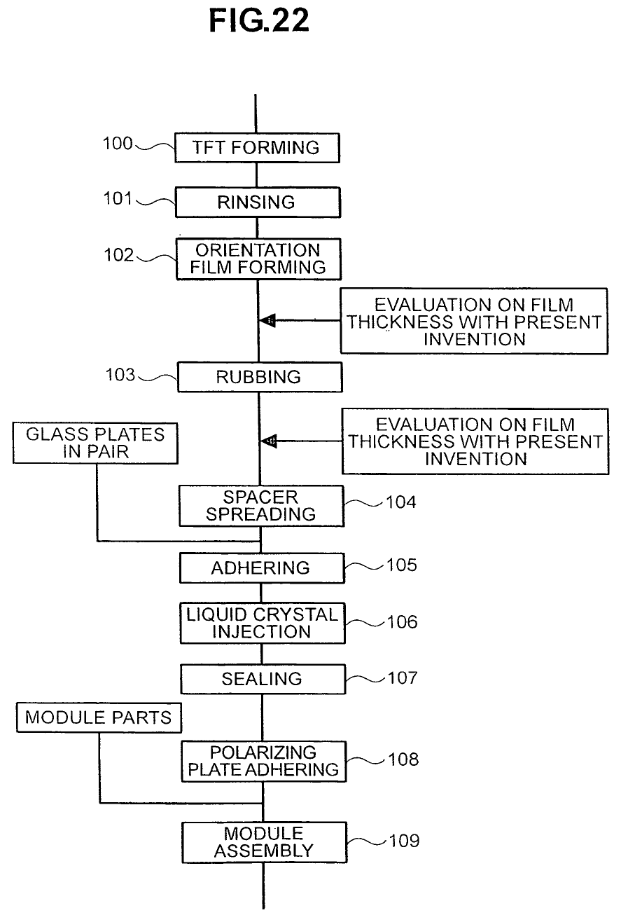

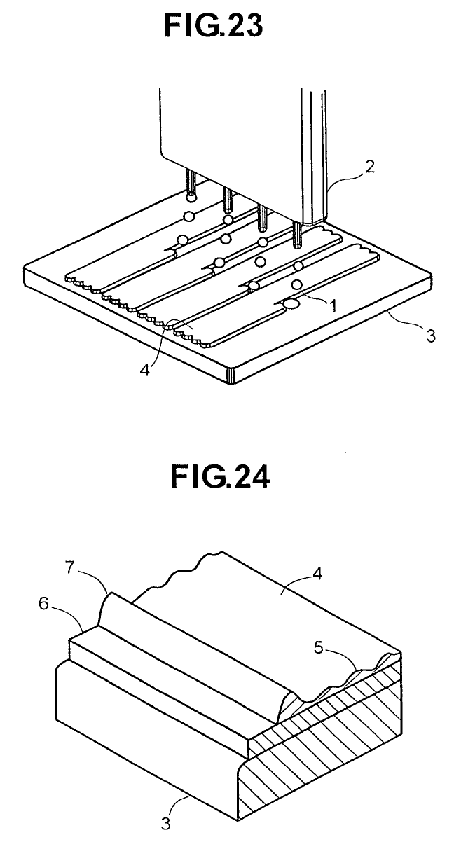

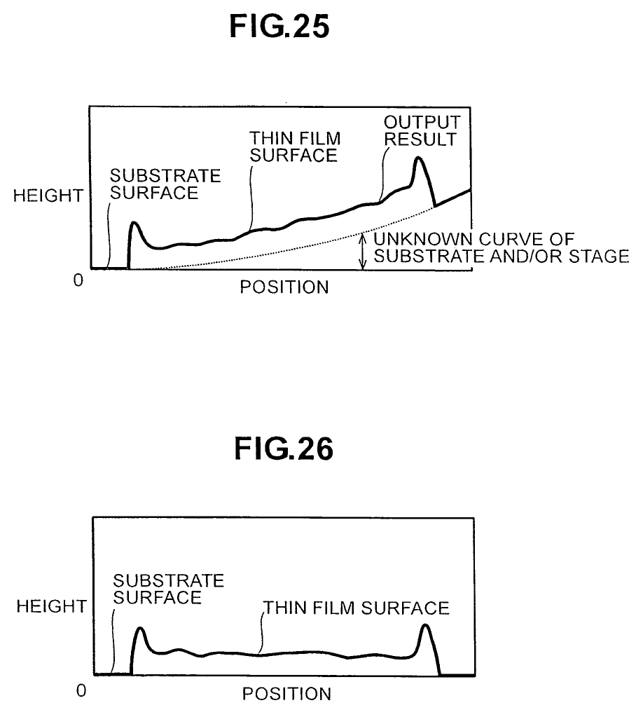

FIG. 22 is a flowchart of manufacturing processes of a flat panel display, into which is applied the measuring method of the thin film thickness, according to the embodiment of the present invention.

In this FIG. 22, upon the flat panel display device, the following are conducted; i.e., forming of TFT, rinsing, and forming of an orientation film (film forming) (steps 100 through 102).

Next, rubbing (step 103) is conducted for controlling the orientation of the liquid crystal. Then, it is manufactured in an order or sequences, such as, spreading of a spacer, adhering or sticking a glass plate together, to be a pair therewith, injection of liquid crystal into a gap defined between the glass plates, which are stuck on each other, sealing of the liquid crystal, adhering or sticking a polarizing plate thereupon, and assembling module parts thereon (steps 104 through 109), etc., for example.

In the steps mentioned above, just after the film forming process (step 102) of the orientation film, such as, the thin film, or just after the rubbing thereof (step 103), the evaluation is made upon the film thickness with using the film thickness measuring apparatus mentioned above, according to the present invention.

Thus, measuring is made on the electrostatic capacitance of the substrate 3, and also the electrostatic capacitance of the substrate 3 and the insulator film 15, and then a measurement is made on the electrostatic capacitance from the substrate 3 up to the thin film 4 covering over the entire surface of the thin film. Then, the thickness of the thin film is calculated out from the electrostatic capacitances measured, the contact area between the probe(s) and the thin film, and the load, etc.

In this manner, introduction of the film thickness evaluation mentioned above, according to the present invention, just after the film forming process or just after the rubbing thereof, enables detection of deficiencies within the formed films, but without waiting the testing on the performances after completion of the assembling thereof, therefore it is possible to remove the substrate of deficiency from the manufacturing process as early as possible. For this reason, it is possible to make a check upon the film forming process, as well as, preventing the cost from generating in the assembling process, which will be conducted thereafter, at the same time.

Furthermore, in the example mentioned above, the probe 10 is so constructed that the load thereof upon the thin film is kept at the constant value, however in the place thereof, it is also possible to dispose a strain sensor at the cantilever 16 or 19, to detect the change of the load of the probe 10 upon the thin film 4, for example, thereby calculating out the contact area through making compensation on the load “P”.

Thus, according to the present invention, it is possible to achieve a method for measuring the thickness of the thin film formed through the conductor layer and the apparatus thereof, being able to eliminate the error on measurement, which is caused due to the curvature or bend on the substrate or on the moving surface of the stage, as well as, to grasp the minute surface configuration covering over a wide region, but without necessitating the large-scaled facility.

Thus, no curvature or bend on the substrate and/or the moving surface of the stage is included into the measurement value, therefore, it is always possible to obtain the thin film at the desired the thickness thereof and also the distribution thereof, purely, and moreover, it is possible to make a measurement covering over a wide region, such as, the entire screen of the flat panel display device, having a large area thereof.

Also, due to the characteristic thereof that the electrostatic capacitance is inversely proportional to the film thickness, the smaller in the film thickness, the higher the sensitivity for measuring thereof; therefore, it is possible to measure the thickness of a thin film, such as, of “nm” order, for example.

Furthermore, since being able to detect the deficiencies within the formed film, but without waiting the performance test after completion of assembling process thereof, the defective substrate can be removed from the manufacturing process as early as possible; therefore, it is possible to prevent the cost from being generated in the assembling process thereafter, as well as, to obtain a check on the film forming process, at the same time.

The present invention may be embodied in other specific forms without departing from the spirit or essential feature or characteristics thereof. The present embodiment(s) is/are therefore to be considered in all respects as illustrative and not restrictive, the scope of the invention being indicated by the appended claims rather than by the forgoing description and range of equivalency of the claims are therefore to be embraces therein.

1. A thin-film thickness measuring method, for measuring thin-film thickness of an insulating thin-film, which is formed on a substrate through at least a conductor layer, comprising the following steps of:
a step for directing said substrate to be in contact with a stage, which is made of a conductor, facing a reverse surface thereof, on a front surface thereof being formed a thin film;
a step for brining a coaxial probe to be in contact with said substrate on a surface thereof, thereby measuring an electrostatic capacitance of said substrate;
a step for brining the coaxial probe to be in contact with said thin film on a surface thereof, so as to make said coaxial probe scanning in a surface direction of the thin film, thereby measuring electrostatic capacitances, each being composed of said substrate and said thin film, at plural numbers of positions; and
a step for calculating and extracting plural numbers of electrostatic capacitive components of said thin film from said electrostatic capacitances measured, thereby converting into thickness of said thin film.

2. The thin-film thickness measuring method, as described in the claim 1, wherein a tip of said coaxial probe is substantially spherical on a surface thereof.

3. The thin-film thickness measuring method, as described in the claim 1, wherein said coaxial probe are provided in plural numbers thereof, and the electrostatic capacitance of said substrate and the composed electrostatic capacitance of said substrate and said thin film are measured, separately, by means of different coaxial probes.

4. The thin-film thickness measuring method, as described in the claim 2, wherein said coaxial probe are provided in plural numbers thereof, and the electrostatic capacitance of said substrate and the composed electrostatic capacitance of said substrate and said thin film are measured, separately, by means of different coaxial probes.

5. The thin-film thickness measuring method, as described in the claim 1, wherein contact pressure between said coaxial probe and said thin film is made nearly equal during a time-period when said coaxial probe scans in the direction of surface direction of the thin film, by means of a probe supporting means, and the thickness of the thin film is converted, by using a contact area between said probe and the thin film, which is calculated out from this contact pressure, a dip radius of said coaxial probe, material property of the probe, and material property of the thin film.

6. The thin-film thickness measuring method, as described in the claim 1, wherein contact pressure between said coaxial probe and said thin film is detected, and the thickness of the thin film is converted, by using a contact area between said probe and the thin film, which is calculated out from this contact pressure, a dip radius of said coaxial probe, material property of the probe, and material property of the thin film.

7. A thin-film thickness measuring apparatus for measuring thin-film thickness of an insulating thin-film, which is formed on a substrate through at least a conductor layer, comprising:
a stage having a conductor surface for mounting said substrate thereon;
a coaxial probe;
a means for measuring an electrostatic capacitance of said substrate between said coaxial probe and said stage, and also electrostatic capacitances composed of those of said substrate and said thin film;
a means for moving said coaxial probe and said stage, relatively;
a means for calculating and extracting electrostatic capacitive component of said thin film from said electrostatic capacitance measured, thereby converting it into thickness thereof; and
a means for recording therein the thickness converted.

8. The thin-film thickness measuring apparatus, as described in the claim 7, wherein a tip of said coaxial probe is substantially spherical on a surface thereof.

9. The thin-film thickness measuring apparatus, as described in the claim 7, wherein said coaxial probe are provided in plural numbers thereof, and the electrostatic capacitance of said substrate and the composed electrostatic capacitance of said substrate and said thin film are measured, separately, by means of different coaxial probes.

10. The thin-film thickness measuring apparatus, as described in the claim 8, wherein said coaxial probe are provided in plural numbers thereof, and the electrostatic capacitance of said substrate and the composed electrostatic capacitance of said substrate and said thin film are measured, separately, by means of different coaxial probes.

11. The thin-film thickness measuring apparatus, as described in the claim 7, further comprising a probe supporting means for keeping contact pressure between said coaxial probe and said thin film to be nearly equal, during a time-period when said coaxial probe scans in the direction of surface direction of the thin film, wherein the thickness of the thin film is converted, by using a contact area between said probe and the thin film, which is calculated out from this contact pressure, a dip radius of said coaxial probe, material property of the probe, and material property of the thin film.

12. The thin-film thickness measuring apparatus, as described in the claim 7, further comprising a contact pressure detecting means for detecting contact pressure between said coaxial probe and said thin film, wherein the thickness of the thin film is converted, by using a contact area between said probe and the thin film, which is calculated out from this contact pressure, a dip radius of said coaxial probe, material property of the probe, and material property of the thin film.
